(19) United States
(12) Patent Application Publication
(10) Pub. No.: US 2008/0173472 A1
(43) Pub. Date: Jul. 24, 2008

(54) PRINTED CIRCUIT BOARD AND ELECTRONIC APPARATUS

(75) Inventors: Minoru Takizawa, Kanagawa (JP); Kazuhiko Nagao, Tokyo (JP); Kiyokazu Ishizaki, Tokyo (JP); Kuniyasu Hosoda, Saitama (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 11/829,029

(22) Filed: Jul. 26, 2007

(30) Foreign Application Priority Data
Jan. 19, 2007 (JP) 2007-010555

(51) Int. Cl. H05K 1/18; H05K 3/34

(52) U.S. Cl. 174/260; 29/840

(57) ABSTRACT

According to one embodiment, a printed circuit board includes a printed wiring board including a through hole part, an electronic component including a component body and a lead member inserted into the through hole part to be electrically connected thereto, a metal member disposed around and separated from the through hole part, and a solder resist disposed at least around the metal member, at least a part of the component body being mounted on the solder resist

### CROSS-REFERENCE TO RELATED. APPLICATIONS

This application is based upon and claims the benefit of priority from Japanese Patent Application No. 2007-010555, filed Jan. 19, 2007, the entire contents of which are incorporated herein by reference.

### BACKGROUND

1. Field

One embodiment of the invention relates to a printed circuit board, for example, on which an electronic component having a lead member is mounted.

2. Description of the Related Art

There has been a printed circuit board on which an electronic component (an insert component) having a lead member such as a connector component, for example, has been inserted into a through hole part in a printed wiring board and connected by soldering. In the printed circuit board of this type, a main body of the electronic component may crush solder paste applied to the through hole part when reflow heating is conducted for solder connection. This crush may create solder ball. Existence of this solder ball may cause short circuits.

In order to prevent the main body of the electronic component from getting into tight contact with the printed circuit board, utilization of a chip part as a spacer has been considered. It is disclosed by, for example, Japanese patent Application Publication (KOKAI) No. H09-8434.

However, when an embodiment of the invention disclosed in the Japanese patent Application Publication (KOKAI) No. H09-8434 is applied to a high density printed circuit board, it may be sometimes difficult to prepare the chip part having an appropriate size and height as the spacer. Moreover, contact between the lead and the chip part may hinder normal operation.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to an embodiment of the invention;

FIGS. 2A and 2B are exemplary views showing a printed circuit board which is contained in a casing of the portable computer in FIG. 1 according to a first embodiment of the invention;

FIGS. 3A and 3B are exemplary views showing modified shapes of a metal member in the embodiment;

FIGS. 4A to 4D are exemplary views showing a process for manufacturing the printed circuit board in the embodiment;

FIG. 5 is an exemplary view showing a state in which a solder has overflowed from a land in the embodiment; and

FIGS. 6A and 6B are exemplary views showing a printed circuit board which is contained in the casing of the portable computer in FIG. 1 according to a second embodiment of the invention.

### DETAILED DESCRIPTION

Various embodiments according to the invention will be described hereinafter with reference to the accompanying drawings. In general, according to one embodiment of the invention, a printed circuit board includes: a printed wiring board including a through hole part; an electronic component including: a component body; and a lead member inserted into the through hole part to be electrically connected thereto; a metal member disposed around and separated from the through hole part; and a solder resist disposed at least around the metal member, at least a part of the component body being mounted on the solder resist.

Now, referring to the drawings, a printed circuit board according to one embodiment of the invention, in which the printed circuit board is applied, for example, to a portable computer, which is one of the electronic apparatuses, will be described.

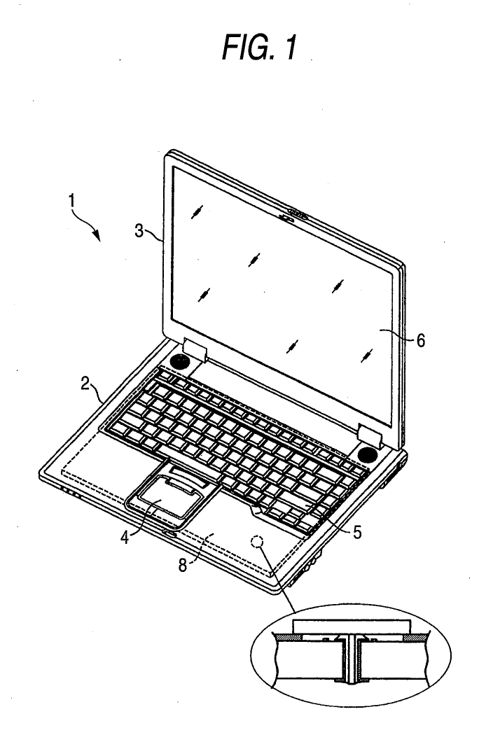

FIG. 1 is an exemplary perspective view of the portable computer according to the one embodiment of the invention. In FIG. 1, a portable computer 1 has a main body 2 and a display casing 3 which is rotatably attached to the main body 2 by means of a hinge mechanism. The main body 2 includes an operation part including a pointing device 4, a keyboard 5 and so on. The display casing 3 includes a display device 6 such as an LCD.

The main body 2 also includes a printed circuit board (a mother board) 8 in which a control circuit for controlling the aforesaid operation part including the pointing device 4, keyboard 5, etc. and the display device 6 is incorporated.

### First Embodiment

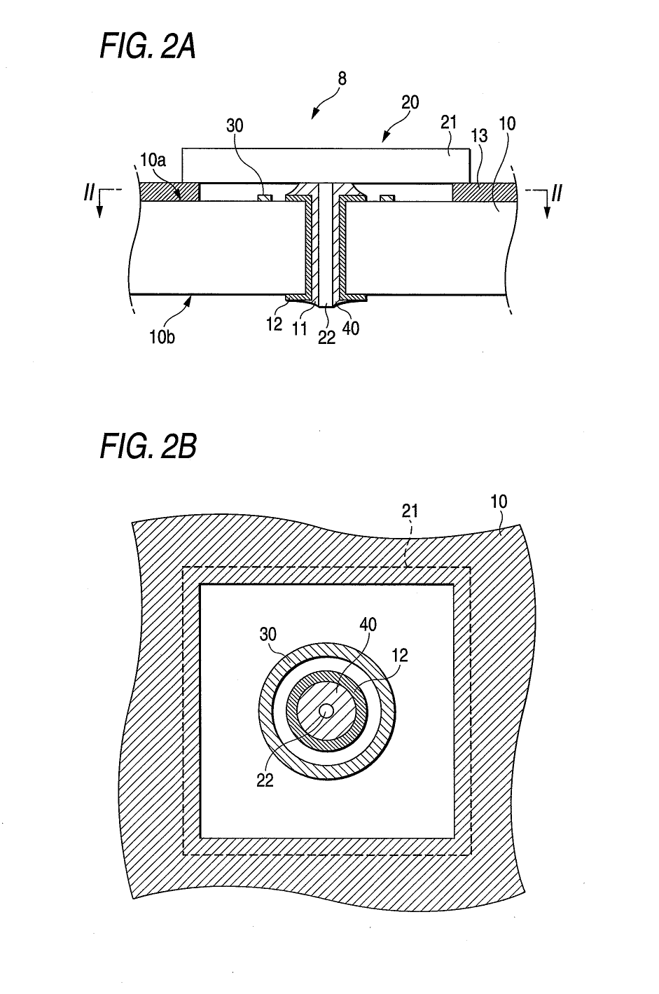

FIGS. 2A and 2B are exemplary views showing a printed circuit board which is contained in a casing of the portable computer as shown in FIG. 1 according to a first embodiment of the invention. FIG. 2A is a sectional view of the printed circuit board, and FIG. 2B is a sectional view taken along a line II-II in FIG. 2A. It is to be noted that an outline of a component body 21 is also shown by a dotted line, in FIG. 2B, for convenience in understanding.

The printed circuit board 8 has a printed wiring board 10 and an electronic component 20.

The printed wiring board 10 has a first face 10a, a second face 10b, and a through hole part 11 which passes through the first and second faces 10a, 10b, and functions as a through hole. Although only one through hole part 11 is shown in FIG. 2, a plurality of through hole parts 11 may be formed, in case where the electronic component 20 which will be described below has a plurality of leads. In addition, a land 12 is formed at an edge of the through hole part 11.

It does not matter whether the printed wiring board 10 is a monolayered board or a multilayered board. The printed wiring board 10 may include wirings and electrodes on both the first face 10a and the second face 10b, and also in an inner layer in case of the multilayered board.

A solder resist 13 is applied to the first face 10a. This solder resist 13 is applied outside a metal member 30 which will be described below.

The electronic component 20 has the component body 21 having a rectangular parallelepiped shape for example, and a lead member 22 which is projected from the component body 21 and inserted into the through hole part 11 to be connected by soldering. Although the electronic component 20 in this embodiment has a single lead member 22 as shown in FIG. 2, a plurality of lead members 22 may be provided according to types of the electronic component.

The metal member 30 is disposed on the first face 10a on which the component body 21 is mounted.

The metal member 30 is disposed around the through hole part 11 and separated from the through hole part 11. The metal member 30 functions to block the solder which has been unable to stay on the land 12, so that the solder may not flow outward from the metal member 30.

The metal member 30 is formed of metal such as copper, which is the same as the material for the land 12. The metal member 30 is disposed between the land 12 and the solder resist 13. Specifically, the metal member 30 is formed in an annular shape on the first face 10a, and arranged outside the land 12 and inside the solder resist 13, as shown in FIG. 2B. The metal member 30 is disposed in a state separated from the through hole part 11. In this embodiment, the metal member 30 is disposed at a position more close to the land 12 than to the solder resist 13. Position of the metal member 30 is not limited to the position more close to the land 12, provided that a flow of the solder overflowed from the land 12 can be blocked.

In other words, the position of the metal member 30 may be an intermediate position between the land 12 and the solder resist 13, or may be a position more close to the solder resist 13.

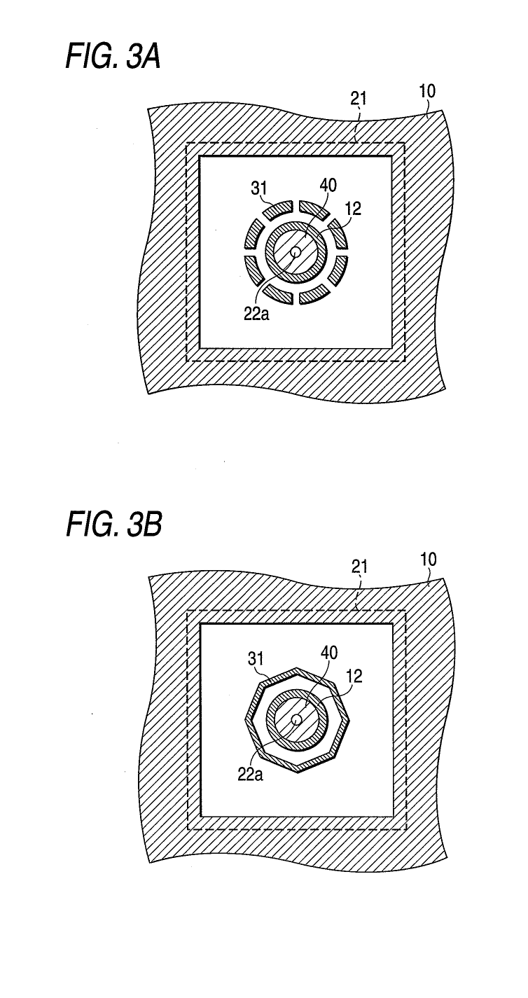

FIGS. 3A and 3B are exemplary views showing modified shapes of the metal member 30. As shown in FIGS. 3A and 3B, the shape of the metal member 30 is not limited to the annular shape. Specifically, the metal member may be in such a shape as divided into a plurality of pieces, although it has a substantially annular shape, as shown in FIG. 3A, provided that the flow of the solder which has overflowed from the land 12 can be blocked. Alternatively, the metal member may be in a polygonal annular shape such as an octagonal shape, as shown in FIG. 3B.

The metal member 30 is thinner in thickness than the solder resist 13. For example, the metal member 30 may have the same thickness as the land 12. However, considering a case of the solder having high fluidity, it would be preferable that the thickness of the metal member 30 is not extremely thinner than that of the land 12. This is because, in some cases, a flow of a solder 40 cannot be blocked by the metal member 30.

In this manner, the metal member 30 is disposed directly below the component body 21 between the land 12 and the solder resist 13, and has a function of blocking the flow of the solder which has overflowed from the land 12.

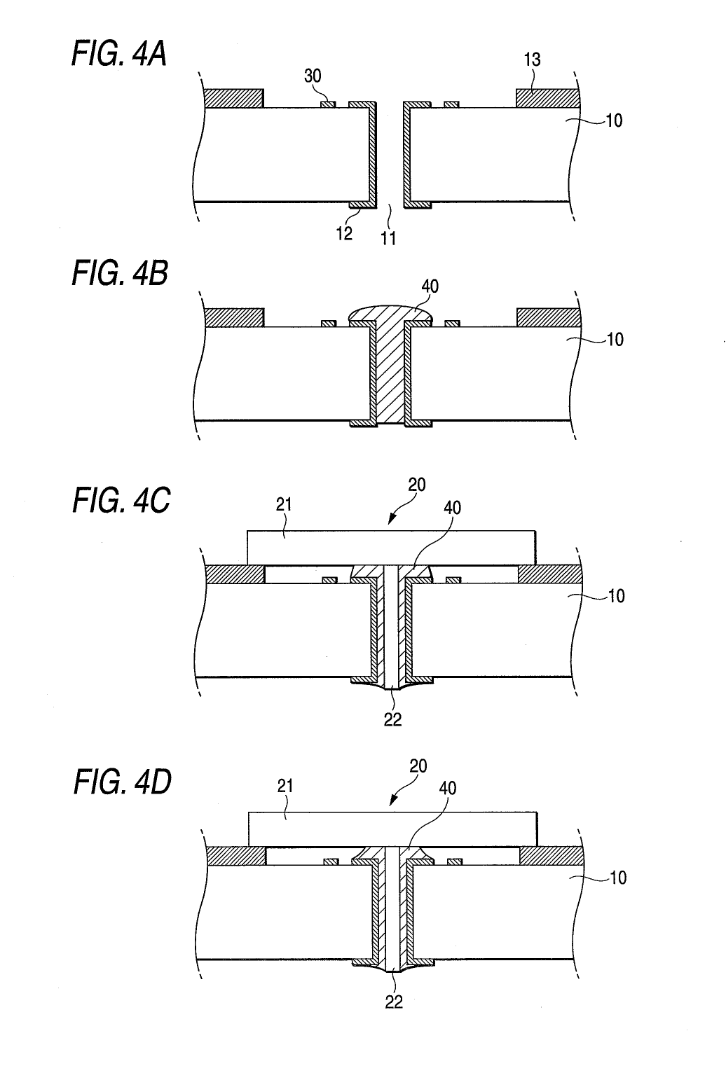

FIGS. 4A to 4D are exemplary views showing a process for manufacturing the printed circuit board in the one embodiment according to the invention. In FIGS. 4A to 4D, the printed circuit board in the above described first embodiment will be described as an example.

As a first step, the printed wiring board 10 which has the through hole part 11 including land 12, and the metal member 30 disposed between the land 12 and the solder resist 13 will be prepared (a wiring board preparing step, step S1). The metal member 30 may be disposed by chemical etching or so, in the same manner as in the case where the land 12 or wirings (not shown) are disposed. Alternatively, the metal member 30 may be disposed by bonding it to the first face 10a by adhesive or the like.

Then, as shown in FIG. 4B, the solder paste will be applied to the through hole part 11 (a solder applying step, step S2). In this solder applying step, a metal mask having an opening in an area to which the solder is applied will be placed on the printed wiring board 10, and the solder paste will be applied over this metal mask. Then, the solder which has been applied over the metal mask will be uniformly spread by means of a determined tool such as a squeegee. In this manner, the solder will be applied through the opening.

Then, as shown in FIG. 4C, the electronic component 20 having the component body 21 and the lead member 22 will be mounted on the printed wiring board 10 by inserting the lead member 22 into the through hole part 11 (a mounting step, step S3).

This mounting step will be conducted by employing a mounting machine such as a mounter.

Thereafter, as shown in FIG. 4D, the printed wiring board 10 on which the electronic component 20 has been mounted will be heated to perform the solder connection (a heating step, step S4). In this heating step, heating treatment according to a determined temperature profile will be conducted by employing a reflow furnace, for example.

Through the above described steps from the steps Si to S4, the component body 21 will be pressed onto the solder resist 13 to be mounted. On this occasion, in case where an amount of the solder 40 which has been applied is larger than a determined amount, the solder 40 will be crushed between the component body 21 and the first face 10a. In some cases, the solder 40 cannot stay in the through hole part 11 and on the land 12, but will spill over (overflow) outward from the land 12.

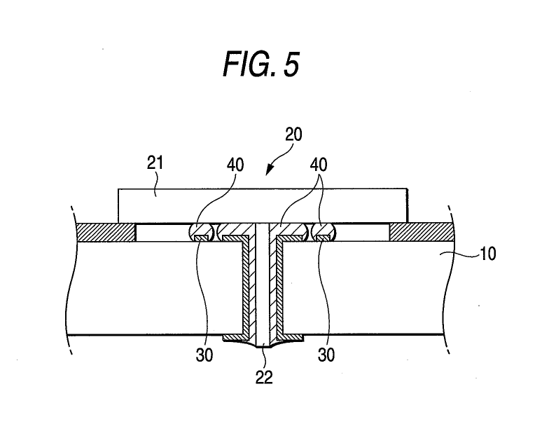

FIG. 5 is a view showing a case where the solder 40 has overflowed from the land 12. Because the printed circuit board 8 includes the metal member 30, the solder 40 which has overflowed will stay in an area having the metal member 30, as shown in FIG. 5. Moreover, because the metal member 30 is formed of copper which is compatible with the solder, the solder will be set as it stays on the metal member 30. As the results, the solder 40 will not reach the solder resist 13 which exists outside the metal member 30.

Further, because the metal member 30 is not electrically connected to other electrodes and wirings, there will not be such anxiety that short circuits may occur between the metal member 30 and the other electrodes and wirings, even though the solder 40 which has overflowed from the through hole part 11 has adhered to the metal member 30. Therefore, it is possible to assure quality of mounting the insert component even in the high-density printed circuit board in which a distance between the lead members is short.

### Second Embodiment of the Printed Circuit Board

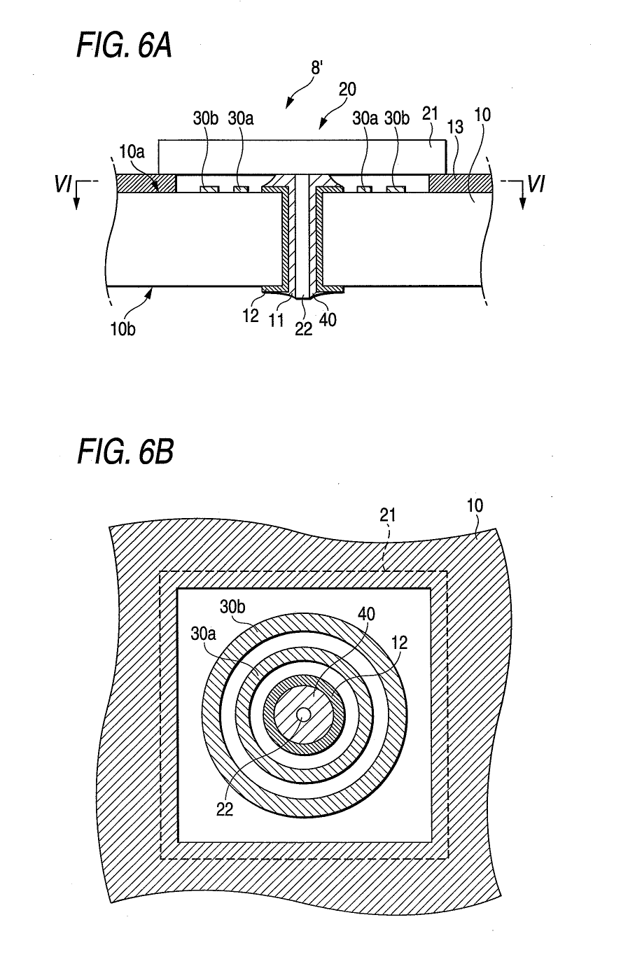

FIGS. 6A and 6B are exemplary views showing a printed circuit board which is contained in the casing of the portable computer as shown in FIG. 1 according to a second embodiment of the invention. FIG. 6A is an exemplary sectional view of the printed circuit board, and FIG. 6B is an exemplary sectional view taken along a line VI-VI in FIG. 6A. It is to be noted that an outline of the component body 21 is also shown by a dotted line, in FIG. 6B, for convenience in understanding.

In FIG. 6, the same parts as those in the first embodiment in FIG. 2 will be denoted with the same reference numerals, and description of them will be omitted. This embodiment is different from the first embodiment in that a plurality of the metal members 30 in the first embodiment is disposed on a printed circuit board 8′.

Specifically, the metal member in this embodiment includes two metal members, namely, a first metal member (also referred to as “a metal member 30a”) which is the same as that in the first embodiment, and another metal member (also referred to as “a metal member 30b”) which is disposed outside the first metal member.

As the positions of the metal members, the metal member 30a is disposed outside the land 12 and close to the land 12 in the same manner as shown in FIG. 2. The metal member 30b is positioned on the first face 10a, and arranged outside the metal member 30a and inside the solder resist 13. In FIG. 6, the metal member 30b is disposed at a position more close to the metal member 30a.

The positions of the metal members 30a, 30b are not particularly limited, except that they must be positioned between the land 12 and the solder resist 13, provided that the overflow of the solder 40 can be blocked.

The metal members 30a, 30b may be disposed by chemical etching or so, in the same manner as in the case where the land 12 or the wirings (not shown) are disposed. Alternatively, the metal members 30a, 30b may be disposed by bonding them to the first face 10a by adhesive or the like.

Although both the metal members 30a, 30b are formed in an annular shape, in FIG. 6, the shape of the metal members 30a, 30b is not limited to the annular shape. Specifically, the metal members may be in such a shape as divided into a plurality of pieces, although it has a substantially annular shape, as shown in FIG. 3A, provided that the flow of the solder which has overflowed from the land 12 can be blocked. Alternatively, the metal members may be in a polygonal annular shape, as shown in FIG. 3B.

Even with the printed circuit board 8′ which has been described above, there will be such a case that the solder 40 may not stay in the through hole part 11 and on the land 12, but spill outward from the land 12 in the manufacturing steps.

The solder 40 which has overflowed will stay in the area of the metal member 30a. Moreover, because the metal member 30a is formed of copper which is compatible with the solder, the solder will be set as it stays on the metal member 30a.

Further, in this embodiment, the other metal member 30b is also disposed outside the metal member 30a. Therefore, in case where the solder 40 which has overflowed is in such an amount that the flow cannot be blocked only by the metal member 30a, it would be possible to further block the flow by the metal member 30b too. As the results, the solder 40 will not reach the solder resist 13 which exists outside the metal members 30a, 30b.

Still further, because the metal member 30 is not electrically connected to the other electrodes and wirings, the solder 40 which has overflowed from the through hole part 11 will not make short circuits with the other electrodes and wirings, even though the solder has adhered to the metal members 30a, 30b. Accordingly, it is possible to assure quality of mounting the insert component even on a high-density printed circuit board in which a distance between the lead members 22 is short.

While certain embodiments of the inventions have been described, these embodiments have been presented by way of example only, and are not intended to limit the scope of the inventions. Indeed, the novel methods described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed circuit board comprising:
a printed wiring board comprising a through hole part;
an electronic component comprising:
a component body; and
a lead member inserted into the through hole part to
be electrically connected thereto;
a metal member disposed around and separated from the through hole part; and
a solder resist disposed at least around the metal member, at least a part of the component body being mounted on the solder resist.

2. The printed circuit board according to claim 1,
wherein the metal member has an annular shape.

3. The printed circuit board according to claim 1,
wherein the metal member has a polygonal annular shape.

4. The printed circuit board according to claim 2,
wherein the metal member is divided into a plurality of pieces and has a substantially annular shape as a whole.

5. The printed circuit board according to claim 1,
wherein the metal member comprises:
a first metal member; and
a second metal member disposed outside the first metal member.

6. The printed circuit board according to claim 1,
wherein the lead member projects from the component body.

7. The printed circuit board according to claim 1,
wherein the lead member is electrically connected to the through hole part by soldering.

8. The printed circuit board according to claim 1,
wherein the component body is mounted on a first face of the printed wiring board, and
wherein the metal member is disposed on the first face.

9. The printed circuit board according to claim 8,
wherein the solder resist is disposed on the first face.

10. An electronic apparatus comprising:
a casing; and
a printed circuit board which is contained in the casing, the printed circuit board comprising:
a printed wiring board comprising a through hole part;
an electronic component comprising:
a component body; and
a lead member inserted into the through hole part to be electrically connected thereto;
a metal member disposed around and separated from the through hole part;
a solder resist disposed at least around the metal member, a part of the component body being mounted on the solder resist.

11. A method for manufacturing a printed circuit board, comprising:
forming a through hole part in a printed wiring board;
disposing a metal member around and separated from the through hole part;
disposing a solder resist at least around the metal member;
applying a solder paste to the through hole part;
inserting a lead member of an electronic component into the through hole part;
mounting at least a part of a component body of the electric component on the solder resist; and
soldering the electronic component to the printed wiring board.
